(19) United States
(12) Patent Application Publication
(10) Pub. No.: US 2026/0128218 A1
(43) Pub. Date: May 7, 2026

(54) METHOD FOR FORMING CAPACITOR ELECTRODE

(71) Applicant: JUSUNG ENGINEERING CO., LTD., Gwangju-si, Gyeonggi-do (KR)

(72) Inventors: Young Woon KIM, Gwangju-Si, Gyeonggi-Do (KR); Yoon Ju LEE, Gwangju-Si, Gyeonggi-Do (KR); Chul Joo HWANG, Gwangju-Si, Gyeonggi-Do (KR)

(21) Appl. No.: 18/860,092

(22) PCT Filed: Apr. 13, 2023
(86) PCT No.: PCT/KR2023/005030

§ 371 Date: Dec. 11, 2025

(30) Foreign Application Priority Data
Apr. 26, 2022 (KR) 10-2022-0051438

(51) Int. Cl. H01G 4/008; C23C 16/455

(52) U.S. Cl. CPC H01G 4/008; C23C 16/4554

(57) ABSTRACT

A method for forming a capacitor electrode in accordance with the exemplary embodiment of the present disclosure includes preparing a substrate, forming a first thin film containing titanium (Ti) by injecting a source containing titanium on the substrate, and forming a second thin film by injecting a source containing a noble metal element or copper (Cu) on the substrate. Accordingly, in accordance with exemplary embodiments of the present disclosure, it is possible to suppress or prevent damage to an underlayer during electrode formation. In addition, it is possible to lower the resistivity of the electrode, and there is an effect of improving electrical characteristics of the electrode. In addition, there is an effect of improving quality characteristics of a capacitor as damage to the underlayer is suppressed or prevented and the electrical characteristics of the electrode are improved.

### TECHNICAL FIELD

The present disclosure relates to a method for forming a capacitor electrode, and more particularly, to a method for forming a capacitor electrode capable of suppressing or preventing damage to an underlayer.

### BACKGROUND ART

A capacitor applied to a semiconductor device includes a lower electrode formed on a substrate, a dielectric layer formed on the lower electrode, and an upper electrode formed on the dielectric layer. Here, each of the upper electrode and the lower electrode is formed by stacking a titanium nitride (TiN) thin film and a tungsten (W) thin film.

The titanium nitride (TiN) thin film is formed using a source containing TiCl₄, and the tungsten (W) thin film is formed using a source containing WF₆.

However, when each of the titanium nitride (TiN) thin film and the tungsten (W) thin film is formed, chlorine (Cl) and fluorine (F) contained in the sources permeate into an underlayer, for example, a contact layer made of metal oxide. Accordingly, there is a limitation in that the underlayer, that is, the contact layer, is damaged, and thus the characteristics of the capacitor deteriorate.

[Prior Art Document] (Patent Document 1)

(Patent Document 1) Korean Patent No. 10-1110077

### DISCLOSURE OF THE INVENTION

### Technical Problem

The present disclosure provides a method for forming a capacitor electrode capable of suppressing or preventing damage to an underlayer.

The present disclosure also provides a method for forming a capacitor electrode capable of improving electrical characteristics.

### Technical Solution

In accordance with an exemplary embodiment, a method for forming a capacitor electrode includes preparing a substrate, forming a first thin film containing titanium (Ti) by injecting a source containing titanium on the substrate, and forming a second thin film by injecting a source containing a noble metal element or copper (Cu) on the substrate.

The forming of the first thin film and the forming of the second thin film may be alternately repeated.

The forming of the second thin film may be performed before the forming of the first thin film.

In the forming of the first thin film, TiN atomic layer deposition may be continuously performed a plurality of times.

In the forming of the second thin film, a plurality of deposition cycles may be continuously performed.

The forming of the first thin film may be repeated more times than the forming of the second thin film.

A ratio (T₁:T₂) of the number of times (T₁) the forming of the first thin film is executed to the number of times (T₂) the forming of the second thin film is executed may be adjusted to 1:1 to 10:1.

The source containing a noble metal element may be a precursor containing at least one of ruthenium (Ru), platinum (Pt), gold (Au), silver (Ag), rhodium (Rh), palladium (Pd), osmium (Os), iridium (Ir), yttrium (Yi), and molybdenum (Mo).

The forming of the second thin film may include injecting a reducing gas after injecting the source containing a noble metal element or copper (Cu) and activating the reducing gas using plasma.

The forming of the second thin film may include injecting a reducing gas after injecting the source containing a noble metal element or copper (Cu) and exposing the substrate to plasma.

### Advantageous Effects

In accordance with exemplary embodiments, it is possible to suppress or prevent damage to an underlayer during electrode formation. In addition, it is possible to lower resistivity of an electrode, and there is an effect of improving electrical characteristics of the electrode.

In addition, as damage to the underlayer is suppressed or prevented and the electrical characteristics of the electrode are improved, there is an effect of improving quality characteristics of a capacitor.

### BRIEF DESCRIPTION OF THE DRAWINGS

FIG. 1 is a diagram conceptually illustrating a capacitor having an electrode formed by a method for forming a capacitor electrode in accordance with exemplary embodiments;

FIG. 2 is a diagram illustrating a lower electrode formed on a substrate having an underlayer formed on an upper surface thereof by the method in accordance with the exemplary embodiment;

FIG. 3 is a conceptual diagram for describing a method for forming the lower electrode by the method in accordance with the exemplary embodiment;

FIG. 4 is a diagram illustrating a lower electrode formed on the substrate having the underlayer formed on the upper surface thereof by a method in accordance with a modification example of the exemplary embodiment;

FIG. 5 is a conceptual diagram for describing a method for forming the lower electrode by the method in accordance with the modification example of the exemplary embodiment; and

FIG. 6 is a diagram illustrating a capacitor having a lower electrode formed on a substrate in which a trench is formed.

### MODE FOR CARRYING OUT THE INVENTION

Hereinafter, an exemplary embodiment of the present disclosure will be described in more detail with reference to the accompanying drawings. However, the present disclosure is not limited to the exemplary embodiment disclosed below, but will be implemented in a variety of different forms. The present exemplary embodiment is only provided to allow the present disclosure to be complete, and to completely inform those skilled in the art of the scope of the disclosure. In order to describe exemplary embodiments of the present disclosure, the drawings may be exaggerated, and the same reference numerals in the drawings refer to the same components.

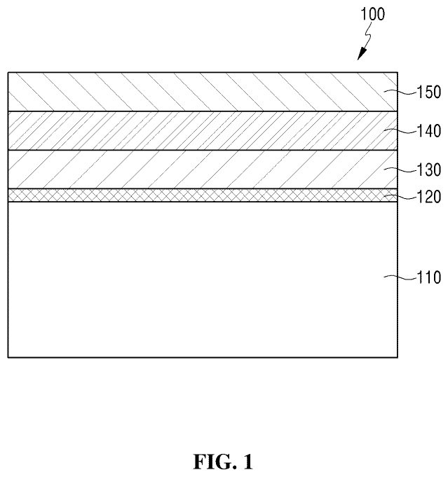

FIG. 1 is a diagram conceptually illustrating a capacitor having an electrode formed by a method for forming a capacitor electrode in accordance with exemplary embodiments.

Referring to FIG. 1, a capacitor 100 may include a substrate 110, a lower electrode 130 formed on the substrate 110, a dielectric layer 140 formed on the lower electrode 130, and an upper electrode 150 formed on the dielectric layer 140. In addition, the capacitor 100 may include an underlayer 120 formed beneath the lower electrode 130, and the underlayer 120 may be, for example, a contact layer.

The substrate 110 may be a semiconductor substrate. As a more specific example, the substrate 110 may be a wafer, and may be any one of a Si wafer, a GaAs wafer, and a SiGe wafer. The underlayer 120 is a layer formed between the substrate 110 and the lower electrode 130 and may be, for example, a contact layer. The underlayer 120 may be formed of a metal oxide, for example, a SiO₂ thin film or an Al₂O₃ thin film.

The dielectric layer 140 may be formed between the lower electrode 130 and the upper electrode 150 and may be formed of a dielectric material including metal oxide. As a more specific example, the dielectric layer 140 may be formed of any one of ZrO₂, Al₂O₃, TiO₂, TaO₂, and HfO₂. In addition, the dielectric layer 140 may be formed by an atomic layer deposition (ALD) method or a chemical vapor deposition (CVD) method.

At least one of the lower electrode 130 and the upper electrode 150 is formed by stacking a first thin film containing titanium (Ti) and a second thin film containing a noble metal element or copper (Cu).

When the second thin film is formed of a thin film containing a noble metal element, a precursor containing the noble metal element is used as a source. More specifically, using, as the source, a precursor containing at least one noble metal element of ruthenium (Ru), platinum (Pt), gold (Au), silver (Ag), rhodium (Rh), palladium (Pd), osmium (Os), iridium (Ir), yttrium (Yi), and molybdenum (Mo), at least one of the lower electrode 130 and the upper electrode 150 is formed. Giving a more specific description, a precursor containing at least one of ruthenium (Ru), platinum (Pt), gold (Au), silver (Ag), rhodium (Rh), palladium (Pd), osmium (Os), iridium (Ir), yttrium (Yi), and molybdenum (Mo) and not containing chlorine (CI) and fluorine (F) is used as the source.

For example, as a precursor source containing ruthenium (Ru), an ethylcyclopentadienyl ruthenium ((EtCp)₂Ru)(Bis(ethylcyclopentadienyl)ruthenium) precursor compound may be used. In addition, as a precursor source containing platinum (Pt), for example, a material containing at least one of (trimethyl)(methylcyclopentadienyl)platinum and trimethyl(cyclopentadienyl)platinum such as may be used. As the precursor source containing gold (Au), for example, gold hydroxide (Au(OH)₃) may be used. As the precursor source containing silver (Ag), for example, a material containing at least one of silver nitrate (AgNO₃) and silver nitrite (AgNO₂) may be used. As the precursor source containing rhodium (Rh), for example, a material containing Rh₄(CO)₁₂ may be used. As the precursor source containing palladium (Pd), for example, a material containing at least one of Pd(NO₃)₂, Pd(OAc)₂, and Pd(acac)₂ may be used. As the precursor sources containing osmium (Os), for example, at least one of (methylcyclopentadienyl)osmium(methyl)(dicarbonyl), (ethylcyclopentadienyl)osmium(methyl)(dicarbonyl) and (propylcyclopentadienyl)osmium(methyl)(dicarbonyl) may be used. As the precursor source containing iridium (Ir), a material containing at least one of Ir(acac)₃ and Ir₄(CO)₁₂ may be used. As the precursor source containing yttrium (Yi), for example, tris-(methylcyclopentadienyl)yttrium may be used. The precursor source containing molybdenum (Mo) may be, for example, a material containing at least one of molybdenum hexacarbonyl and molybdenum pentachloride.

As such, in forming at least one of the lower electrode 130 and the upper electrode 150 by forming the second thin film containing a noble metal element, in the exemplary embodiment, the precursor not containing chlorine (Cl) and fluorine (F), and containing at least one of ruthenium (Ru), platinum (Pt), gold (Au), silver (Ag), rhodium (Rh), palladium (Pd), osmium (Os), iridium (Ir), yttrium (Yi), and molybdenum (Mo) is used as the source. Thus, it is possible to suppress or prevent damage to the layer formed beneath the electrode using the above-mentioned source by chlorine (Cl) and fluorine (F). For example, when the lower electrode 130 is formed using a precursor containing the aforementioned noble metal and not containing chlorine (Cl) and fluorine (F) as the source, it is possible to suppress or prevent damage caused by penetration of chlorine (Cl) and fluorine (F) into the underlayer 120, for example, the contact layer, at the time of forming the lower electrode 130. For another example, when the upper electrode 150 is formed using a precursor containing the above-mentioned noble metal and not containing chlorine (Cl) and fluorine (F) as the source, it is possible to suppress or prevent damage to a layer beneath the upper electrode 150, that is, the dielectric layer 140, by chlorine (Cl) and fluorine (F).

In the above, the formation of the second thin film using the precursor containing a noble metal element as the source has been described, but the second thin film may be formed by using the precursor containing copper (Cu) as the source. In this case, an organometallic compound or a material containing F or Cl may be used as the precursor source including copper (Cu).

Here, as the precursor source containing copper (Cu), which is an organometallic compound, for example, a material containing at least one of Cu(II)-2,2,6,6-tetramethyl-3,5-heptandionate [Cu(thd)₂] and Cu(II) hexafluoroacetylacetonate [Cu(hfac)₂] may be used. In addition, as the copper precursor source containing F or Cl, a material containing at least one of CuCl₁, CuCl₂, CuF₁, CuF₂, CuBr₁, CuBr₂, CuI₁ or CuI₂ may be used.

In addition, noble metal elements such as ruthenium (Ru), platinum (Pt), gold (Au), silver (Ag), rhodium (Rh), palladium (Pd), osmium (Os), iridium (Ir), yttrium (Yi), and molybdenum (Mo) and copper (Cu) have a lower resistivity than tungsten (W), which is a source used in the related art when the upper electrode 150 and the lower electrode 130 are used. Therefore, at least one of the upper electrode 150 and the lower electrode 130 formed using the above-described noble metal materials has a lower resistivity than that in the related art, and thus has an effect of improving electrical characteristics.

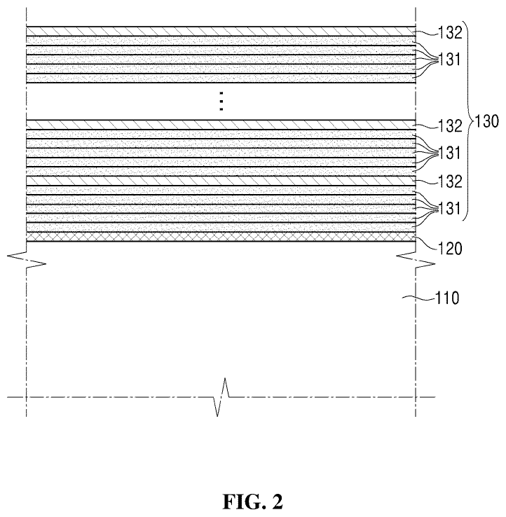

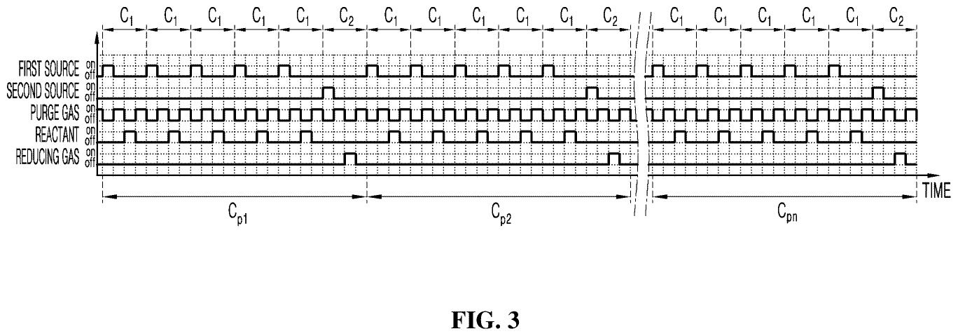

Hereinafter, a method for forming a capacitor electrode by a method in accordance with the exemplary embodiment will be described with reference to FIGS. 2 and 3. In this case, an example will be described in which the lower electrode 130 is formed on top of the underlayer 120 in a state where the underlayer 120 made of metal oxide is formed on top of the substrate 110. Further, since the lower electrode 130 and the upper electrode 150 are formed by the same method, the method for forming the lower electrode 130 will be described and a detailed description of the method for forming the upper electrode 150 will be omitted.

FIG. 2 is a diagram illustrating a lower electrode formed on a substrate having an underlayer formed on an upper surface thereof by the method in accordance with the exemplary embodiment. FIG. 3 is a conceptual diagram for describing a method for forming the lower electrode by the method in accordance with the exemplary embodiment. In this case, “on” in FIG. 3 may mean that the precursor or gas is injected, and “off” may mean that injecting of the precursor or gas is stopped or finished.

Referring to FIG. 2, the lower electrode 130 may include a first thin film 131 containing titanium (Ti) and a second thin film 132 that is a thin film formed on the first thin film 131 and containing a noble metal element. Here, the first thin film 131 may be, for example, a TiN thin film. Further, the first thin film 131 may be formed by a deposition method using a source containing titanium (Ti), and the second thin film 132 may be formed by a deposition method using a source containing a noble metal element or copper (Cu).

The lower electrode 130 may include a plurality (or multiple layers) of first thin films 131 and a plurality (or multiple layers) of second thin films 132. In this case, as illustrated in FIG. 2, the first thin film 131 and the second thin film 132 may be alternately stacked to form the lower electrode 130. In addition, the total number of layers of the first thin film 131 included in the lower electrode 130 may be greater than that of the second thin film 132. In addition, the number of continuously stacked first thin films 131 may be greater than the number of continuously stacked second thin films 132. In addition, when the lower electrode 130 is formed, the thin film that has first deposited may be the first thin film 131 as illustrated in FIG. 2. In other words, in forming the lower electrode 130 on the underlayer 120, the thin film that has been first deposited on an upper surface of the underlayer 120 may be the first thin film 131.

Describing a more specific example with reference to FIG. 2, five layers of the first thin film 131 may be formed on the upper surface of the underlayer 120 and then one layer of the second thin film 132 may be continuously formed on the first thin films 131, and the lower electrode 130 may be formed by alternately repeating the formation of five layers of the first thin film 131 and the formation of one layer of the second thin film 132 a plurality of times. Therefore, the number of stacked first thin films 131 included in the lower electrode 130 may be greater than the number of stacked second thin films 132 included therein, and the number of continuously stacked first thin films 131 may be greater than the number of continuously stacked second thin films 132.

In the above, an example in which the second thin film 132 is not formed continuously in multiple layers, but is formed in one layer or a single layer has been described. However, the second thin film 132 is not limited thereto, and multiple layers of the second thin film 132 may be formed continuously according to the number of continuously stacked thin films including titanium (Ti), that is, the first thin films 131. For example, when ten layers of the first thin film 131 are continuously formed, five layers of the second thin film 132 may be continuously formed. That is, ten layers of the first thin film 131 may be formed on the upper surface of the underlayer 120 and then five layers of the second thin film 132 may be continuously formed on the first thin films 131, and the lower electrode 130 may be formed by alternately repeating the formation of ten layers of the first thin film 131 and the formation of five layers of the second thin film 132 a plurality of times.

Here, the multiple layers of the first thin film 131 or the multiple layers of the second thin film 132 are each formed by repeating the deposition cycle a plurality of times. In addition, in FIG. 2, in order to distinguish the first thin film 131 deposited by each deposition cycle from that deposited by another deposition cycle, multiple layers are illustrated, but the plurality of stacked first thin films 131 may be an integrated film.

Referring to FIG. 3, a process of forming the lower electrode 130 on the substrate 110 or the underlayer 120 includes a process cycle Cp of forming the first thin film 131 and the second thin film 132. In addition, the process cycle Cp is carried out a plurality of times. That is, the process of forming the lower electrode 130 includes a plurality of process cycles (Cp: Cp₁, Cp₂, . . . , Cₚₙ₋₁, Cₚₙ), and each of the plurality of process cycles (Cp: Cp₁, Cp₂, . . . , Cₚₙ₋₁, Cₚₙ) includes a first cycle C₁ of depositing the first thin film 131 containing titanium (Ti) and a second cycle C₂ of depositing a second thin film 132 containing a noble metal element or copper (Cu). In other words, each of the plurality of process cycles (Cp: Cp₁, Cp₂, . . . , Cₚₙ₋₁, Cₚₙ) includes an operation of forming a first thin film 131 and an operation of forming the second thin film 132. Further, the operation of forming the first thin film 131 includes the first cycle C₁, and the operation of forming the second thin film 132 includes the second cycle C₂.

Hereinafter, for convenience of description, the plurality of process cycles (Cp: Cp₁, Cp₂, . . . , Cₚₙ₋₁, Cₚₙ) sequentially executed are referred to as a primary process cycle Cₚ₁ and a secondary process cycle Cₚ₂, . . . , a n-1-th process cycle Cₚₙ₋₁, and a nth process cycle Cₚₙ, respectively. Here, “n” may be a process cycle of the last round. Further, the last round n may vary according to a target number of executions of the process cycle, and the target number of executions of the process cycle may be changed according to a target thickness of the lower electrode 130 to be manufactured.

The process cycle Cₚ of forming the lower electrode 130 of the capacitor 100 includes the operation of forming the first thin film 131 by injecting a source containing titanium (Ti) and the operation of forming the second thin film 132 by injecting a source that is a precursor containing a noble metal element or copper (Cu), and the operation of forming the first thin film 131 and the operation of forming the second thin film 132 are alternately performed a plurality of times.

Hereinafter, the process cycle Cₚ will be described in more detail with reference to FIG. 3. At this time, the primary process cycle Cₚ₁ will be described as an example.

Referring to FIG. 3, the primary process cycle Cₚ₁ includes the first cycle C₁ of depositing the first thin film 131 containing titanium (Ti) and the second cycle C₂ of depositing the second thin film 132 containing a noble metal element or copper (Cu). At this time, the first cycle C₁ may be executed earlier than the second cycle C₂. Accordingly, each of the plurality of process cycles Cₚ may be executed in the order of “the first cycle C₁ and the second cycle C₂”.

Of course, the order of execution of the first cycle C₁ and the second cycle C₂ may not be limited thereto. That is, the second cycle C₂ may be executed earlier than the first cycle C₁. That is, each of the plurality of process cycles Cₚ may be executed in the order of “the second cycle C₂ and the first cycle C₁”.

The first cycle Ci may include an operation of injecting a first source containing Ti (titanium), an operation of injecting a purge gas (first purge), an operation of injecting a reactant, and an operation of injecting a purge gas (second purge). That is, the first cycle C₁ may be a cycle in which “injecting of the first source containing Ti (titanium), injecting of of the purge gas (first purge), injecting of the reactant, and injecting of the purge gas (second purge)” are executed. As the first source containing Ti (titanium), for example, a gas containing TiCl₄ may be used. Further, as a reactant, the gas containing nitrogen (N), for example, a gas containing NH₃ may be used. In addition, Ar gas may be used as a purge gas. A TiN atomic layer, that is, the first thin film 131, is deposited and formed by an atomic layer deposition (ALD) method by the first cycle C₁.

The first cycle C₁of depositing the first thin film 131 in this way may be referred to as a “TiN deposition cycle”.

The second cycle C₂ may include an operation of injecting a second source containing a noble metal element or copper (Cu), an operation of injecting a purge gas (first purge), an operation of injecting a reducing gas, and an operation of injecting a purge gas (second purge).

At this time, the noble metal used as the second source may use a precursor containing at least one of ruthenium (Ru), platinum (Pt), gold (Au), silver (Ag), rhodium (Rh), palladium (Pd), osmium (Os), iridium (Ir), yttrium (Yi), and molybdenum (Mo) and not containing chlorine (Cl) and fluorine (F). In addition, the second source, which is the precursor containing a noble metal element or copper (Cu), may be in a liquid or gaseous state.

In the precursor used as the second source and containing the noble metal element, the precursor containing ruthenium (Ru) may be ethylcyclopentadienyl ruthenium ((EtCp)₂Ru)(Bis(ethylcyclopentadienyl) ruthenium),

and as the precursor containing gold (Au), for example, gold hydroxide (Au(OH)₃) may be used. As the precursor containing silver (Ag), for example, a material containing at least one of silver nitrate (AgNO₃) and silver nitrite (AgNO₂) may be used. As the precursor containing rhodium (Rh), for example, a material containing Rh₄(CO)₁₂ may be used. As the precursor containing palladium (Pd), for example, a material containing at least one of Pd(NO₃)₂, Pd(OAc)₂, and Pd(acac)₂ may be used. As the precursor containing osmium (Os), for example, at least one of (methylcyclopentadienyl)osmium(methyl)(dicarbonyl), (ethylcyclopentadienyl)osmium(methyl)(dicarbonyl) and (propylcyclopentadienyl)osmium(methyl)(dicarbonyl) may be used. As the precursor containing iridium (Ir), a material containing at least one of Ir(acac)₃ and Ir₄(CO)₁₂ may be used. As the precursor containing yttrium (Yi), for example, tris-(methylcyclopentadienyl)yttrium may be used. As the precursor source containing molybdenum (Mo), for example, a material containing at least one of molybdenum hexacarbonyl and molybdenum pentachloride may be used.

In addition, as the precursor containing copper (Cu), a material containing at least one of Cu(II)-2,2,6,6-tetramethyl-3,5-heptandionate [Cu(thd)₂] and Cu(II) hexafluoroacetylacetonate [Cu(hfac)₂] may be used, or a material containing at least one of CuCl₁, CuCl₂, CuF₁, CuF₂, CuBr₁, CuBr₂, CuI₁, or CuI₂ may be used.

Hereinafter, an example in which the precursor containing a noble metal element is used as the second source and the second thin film 132 is formed of a noble metal element thin film will be described. More specifically, an example in which the second thin film 132 is formed of a ruthenium (Ru) thin film using the precursor containing ruthenium (Ru) as the second source will be described.

For the purge gas, the same gas as the gas used in the first cycle C₁ may be used. That is, argon (Ar) gas may be used as the purge gas.

The reducing gas is a gas injected to remove impurities included in the second thin film 132, for example, a ruthenium (Ru) thin film, and a gas containing oxygen (O) or hydrogen (H) may be used. More specifically, the gas containing oxygen (O) may be O₂ gas, and the gas containing hydrogen (H) may be H₂ gas. In addition, this reducing gas may be referred to as gas for removing impurities.

It is desirable to generate plasma or apply heat to a thin film deposition space, for example, inside a chamber, when or after the reducing gas is injected. Thus, the substrate is subjected to plasma treatment or heat treatment. In addition, the reducing gas may be activated by generated plasma or heat.

As such, the second cycle C₂ of forming the second thin film 132 includes “second source injection-purge gas injection (first purge)—reducing gas injection-purge gas injection (second purge),” and the second thin film 132 is deposited and formed by this second cycle C₂. The second cycle C₂ in which the second thin film 132 is formed using the source containing a noble metal element may be referred to as a “noble metal deposition cycle.” In the exemplary embodiment, in executing the first cycle C₁ and the second cycle C₂ as described above, the number of times T₁ the first cycle C₁ included in one process cycle Cₚ is executed is adjusted to be larger than the number of times T₂ the second cycle C₂ is executed. In other words, the number of times T₂ the operation of forming the noble metal thin film included in one process cycle Cₚ is executed is adjusted to be smaller than the number of times T₁ the operation of forming the TiN thin film is executed.

At this time, a ratio T₁:T₂ of the number of times T₁ the first cycle C₁ is executed to the number of times T₂ the second cycle C₂ is executed is adjusted to be 1:1 to 10:1 (T₁:T₂=1:1 to 10:1). More preferably, the ratio T₁:T₂ of the number of times T₁ the first cycle C₁ is executed to the number of times T₂ the second cycle C₂ is executed is adjusted to be 3:1 to 8:1 (T₁:T₂=3:1 to 8:1). In other words, the ratio T₁:T₂ of the number of times Ti the operation of forming the TiN thin film is executed to the number of times T₂ the operation of forming the noble metal thin film is executed is adjusted to be 1:1 to 10:1, more preferably 3:1 to 8:1.

As described above, the first cycle C₁ may be referred to as a “TiN thin film deposition cycle”, and the second cycle C₂ may be referred to as a “noble metal thin film cycle”. Therefore, the “ratio T₁:T₂ of the number of times T₁ the first cycle Ci is executed to the number of times T₂ the second cycle C₂ is executed” may be described as “the ratio T₁:T₂ of the number of times T₁ the TiN thin film deposition cycle C₁ is executed to the number of times T₂ the noble metal thin film deposition cycle C₂ is executed”. Accordingly, the ratio T₁:T₂ of the number of times T₁ the TiN thin film deposition cycle C₁ is executed to the number of times T₂ of the noble metal thin film deposition cycle C₂ is executed may be described as being adjusted to 1:1 to 10:1, more preferably, 3:1 to 8:1.

Hereinafter, for convenience of description, “the ratio T1:T₂ of the number of times T₁ the first cycle C₁ is executed to the number of times T₂ the second cycle C₂ is executed” will be abbreviated as a “first and second cycle execution number ratio T₁:T₂”and described.

For a more specific description of the method for forming the lower electrode 130, a case in which the first and second cycle execution number ratio T₁:T₂ is 5:1 will be described as an example with reference to FIG. 3. Referring to FIG. 3, each of the plurality of process cycles (Cp: Cp₁, Cp₂, . . . , Cₚₙ₋₁, Cₚₙ) may include first and second cycles C₁ and C₂, wherein the first and second cycle execution number ratio T₁:T₂ may be 5:1. That is, each of the plurality of process cycles (Cp: Cp₁, Cp₂, . . . , Cₚₙ₋₁, Cₚₙ) may include five first cycles C₁ and one second cycle C₂ as illustrated in FIG. 3.

When the primary process cycle Cₚ₁ is described as an example, first, the first cycle C₁ is executed five times. Accordingly, as illustrated in FIG. 2, five layers of the first thin film 131 are deposited on the substrate 110 or the underlayer 120. Five first cycles (C₁) are continuously executed, and when the fifth first cycle C₁ is finished, the second cycle C₂ is executed once. Accordingly, one layer of the second thin film 132, that is, a ruthenium (Ru) thin film, is deposited on the first thin film 131. Then, as described above, since the first cycle C₁ is executed continuously five times and then the second cycle C₂ is executed once, the first and second cycle execution number ratio T₁:T₂ is 5:1.

When the second cycle C₂ of the primary process cycle Cₚ₁ is finished in this way, next, the secondary process cycle Cₚ₂ is executed. At this time, it is desirable to execute the secondary process cycle Cₚ₂ at the same ratio as the first and second cycle execution number ratio T₁:T₂ in the primary process cycle Cₚ₁. That is, in executing the secondary process cycle Cₚ₂, the first and second cycle execution number ratio T₁:T₂ is set to 5:1.

When the second cycle C₂ of the secondary process cycle Cₚ₂ is finished, the next process cycles Cp₃, . . . , Cₚₙ₋₁, Cₚₙ are executed in the same manner. At this time, as illustrated in FIG. 3, the process cycle is executed until a desired number of times n is reached.

As described above, in the exemplary embodiment, in forming the lower electrode 130, when the second thin film 132 is formed, the second thin film 132 is formed using the noble metal precursor not containing chlorine (Cl) and fluorine (F). That is, the second thin film 132 is formed by using the precursor containing at least one of ruthenium (Ru), platinum (Pt), gold (Au), silver (Ag), rhodium (Rh), palladium (Pd), osmium (Os), iridium (Ir), yttrium (Yi), and molybdenum (Mo) and not containing chlorine (CI) and fluorine (F) as the second source. Accordingly, it is possible to suppress or prevent damage to the underlayer 120, for example, the contact layer, formed beneath the lower electrode 130 by chlorine (Cl) and fluorine (F). That is, when the lower electrode 130 is formed, damage to the underlayer 120 due to chlorine (Cl) and fluorine (F) may be suppressed or prevented. Accordingly, deterioration in characteristics of the capacitor 100 due to damage to the underlayer 120 may be suppressed or prevented. In addition, by forming the lower electrode 130 by the method in accordance with the exemplary embodiment, damage to the underlayer 120 may be suppressed compared to the related art. Giving a more specific description of it, in the case of the exemplary embodiment, the first thin film 131 is first formed on the underlayer 120 using a TiCl₄ source, and the second thin film 132 containing a noble metal element is formed on the TiN thin film. Accordingly, a small amount of damage due to chlorine (Cl) may occur when the first thin film 131 is formed on the underlayer 120.

However, this damage may be less than that of the method in the related art in which each of the two layers to be stacked is used as the source containing chlorine (Cl) and fluorine (F). That is, in the case of the related art, a TiN thin film is formed using a TiCl₄ source, a tungsten (W) thin film is formed using a WF₆ source, and a lower electrode is formed by alternately stacking the TiN thin film and the tungsten (W) thin film. In other words, one of the two types of thin films constituting the lower electrode is formed using the source containing chlorine (Cl), and the other is formed using the source containing fluorine (F). Accordingly, when the TiN thin film and the tungsten (W) thin film are formed, chlorine (Cl) and fluorine (F) may penetrate into the underlayer and damage the underlayer.

On the other hand, in the case of the exemplary embodiment, one of the thin films constituting the lower electrode 130, that is, the first thin film 131 containing a noble metal element, is formed using a source not containing chlorine (Cl) and fluorine (F). Thus, as compared with the related art, damage to the underlayer 120 due to chlorine (Cl) and fluorine (F) when the lower electrode 130 is formed may be suppressed.

In addition, although it has been described above that the second thin film 132 is formed of the thin film containing a noble metal element, the second thin film 132 may be formed of the thin film containing copper (Cu).

As described above, as the lower electrode 130 is formed to contain a noble metal element containing at least one of ruthenium (Ru), platinum (Pt), gold (Au), silver (Ag), rhodium (Rh), palladium (Pd), osmium (Os), iridium (Ir), yttrium (Yi), and molybdenum (Mo) or copper (Cu), the resistivity of the lower electrode 130 may be reduced. That is, as compared to the case of forming the lower electrode 130 with tungsten (W) in the related art, in the case of the exemplary embodiment, the resistivity of the lower electrode 130 may be lowered, and thus there is an effect of improving electrical characteristics.

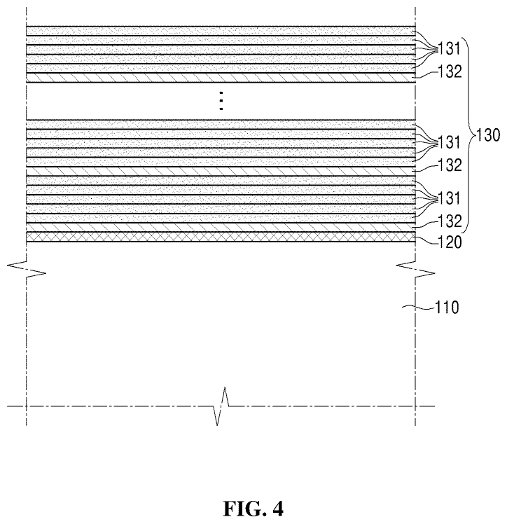

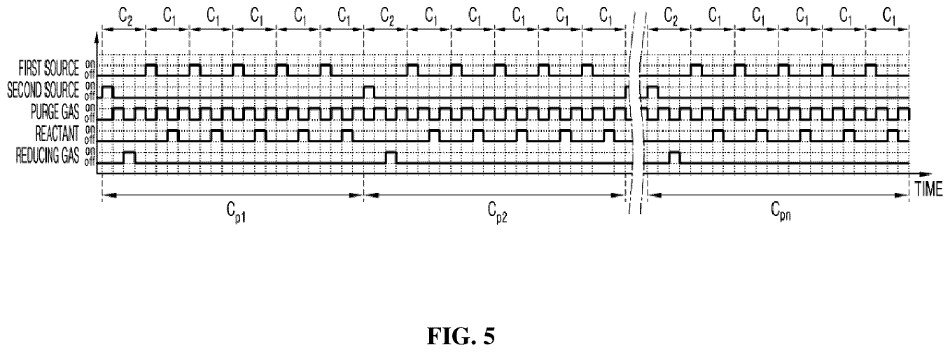

FIG. 4 is a diagram illustrating a lower electrode formed on the substrate having the underlayer formed on the upper surface thereof by a method in accordance with a modification example of the exemplary embodiment. FIG. 5 is a conceptual diagram for describing a method for forming the lower electrode by the method in accordance with the modification example of the exemplary embodiment.

In the above-described exemplary embodiment, in forming the lower electrode 130, it has been described that the operation of depositing the TiN thin film, that is, the first cycle C₁, is first executed. However, the formation of the lower electrode 130 is not limited thereto, and an operation of depositing a thin film containing a noble metal element or copper (Cu), that is, the second cycle C₂, may be first executed. Accordingly, a layer formed on the upper surface of the underlayer 120 or a layer formed to directly contact the underlayer 120 may be the second thin film 132 as illustrated in FIG. 4.

Hereinafter, the method for forming the lower electrode 130 on the underlayer 120 by the method in accordance with the modification example will be described with reference to FIGS. 4 and 5. Here, descriptions of parts overlapping with those described in the exemplary embodiment will be omitted or briefly described.

Referring to FIG. 5, a process of forming the lower electrode 130 includes a process cycle Cₚ of forming the second thin film 132 and the first thin film 131 on the substrate 110 or the underlayer 120. In addition, the process of forming the lower electrode 130 includes a plurality of process cycles Cₚ.

Each of the plurality of process cycles (Cp: Cp₁, Cp₂, . . . , Cₚₙ₋₁, Cₚₙ) includes the second cycle C₂ of forming the second thin film 132 and the first cycle C₁ of forming the first thin film 131. That is, each of the plurality of process cycles (Cp: Cp₁, Cp₂, . . . , Cₚₙ₋₁, Cₚₙ) includes the operation of forming the thin film containing a noble metal element or copper (Cu) and the operation of forming the thin film containing titanium (Ti).

At this time, the second cycle (C₂) is first executed before the first cycle (C₁) is executed. That is, the operation of forming the thin film containing a noble metal element or copper (Cu) is first performed before the operation of forming the TiN thin film. In other words, the second cycle C₂ is first executed so that the thin film deposited on the upper surface of the underlayer 120 or in contact with the underlayer 120 is the second thin film 132.

Then, as in the above-described exemplary embodiment, the second cycle C₂ and the first cycle C₁ are alternately executed a plurality of times. At this time, the number of times T₂ the second cycle C₂ included in one process cycle Cₚ is executed is adjusted to be smaller than the number of times T₁ the first cycle C₁ is executed. That is, in one process cycle Cₚ, the number of times T₂ the second cycle C₂ is continuously executed is adjusted to be smaller than the number of times T₁ the first cycle Ci is continuously executed.

In addition, the ratio T₁:T₂ of the number of times Ti the first cycle Ci is executed to the number of times T₂ the second cycle C₂ is executed is adjusted to be 1:1 to 10:1 (T₁:T₂=1:1 to 10:1), more preferably, to 3:1 to 8:1 (T₁:T₂=3:1 to 8:1).

Giving a more specific description with reference to FIG. 5, each of the plurality of process cycles (Cp: Cp₁, Cp₂, . . . , Cₚₙ₋₁, Cₚₙ) may include one second cycle C₂ and five first cycles C₁. When the primary process cycle Cₚ₁ is described as an example, first, the second cycle C₂ is executed once. Then, as illustrated in FIG. 4, one layer of the second thin film 132 is deposited on the underlayer 120. When the second cycle C₂ of one time is finished, the first cycle C₁ is executed five times. Accordingly, five layers of the first thin film 131 are formed on the second thin film 132, for example, a ruthenium (Ru) thin film. Then, as described above, since the second cycle C₂ is executed once and then the first cycle C₁ is executed five times in succession, the first and second cycle execution number ratio T₁:T₂ is 5:1.

When the first cycle C₁ of the primary process cycle Cₚ₁ is finished in this way, next, the secondary process cycle Cₚ₂ is executed. At this time, it is desirable to execute the secondary process cycle Cₚ₂ at the same ratio as the first and second cycle execution number ratio T₁:T₂ in the primary process cycle Cₚ₁.

When the second cycle C₂ of the secondary process cycle Cₚ₂ is finished, the next process cycles Cₚ₃, . . . , Cₚₙ₋₁, Cₚₙ are executed in the same manner. At this time, as illustrated in FIG. 5, the process cycle is executed until a desired number of times n is reached.

As described above, in the case of the modification example, in forming the lower electrode 130 on the underlayer 120, the second thin film 132 deposited using the second source not containing chlorine (Cl) and fluorine (F) is first formed.

Accordingly, in the case of the modification example, damage to the underlayer 120 may be more effectively suppressed or prevented as compared to the exemplary embodiment. That is, in the case of the exemplary embodiment, the first thin film 131 is first formed on the underlayer 120 using the TiCl₄ source, and the second thin film 132 is formed on the first thin film 131. On the other hand, in the case of the modification example, in forming the lower electrode 130, the second thin film 132 is first formed. That is, the second thin film 132 is first formed on the underlayer 120 by using the precursor containing at least one of ruthenium (Ru), platinum (Pt), gold (Au), silver (Ag), rhodium (Rh), palladium (Pd), osmium (Os), iridium (Ir), yttrium (Yi), and molybdenum (Mo) and not containing chlorine (Cl) and fluorine (F). Then, the first thin film 131 is formed on the second thin film 132 using TiCl₄ as the source. Accordingly, as the underlayer 120 is covered with the second thin film 132, the underlayer 120 may be prevented from being exposed to chlorine (Cl) when the first thin film 131 is formed. Therefore, damage to the underlayer 120 may be more effectively suppressed or prevented than in the exemplary embodiment.

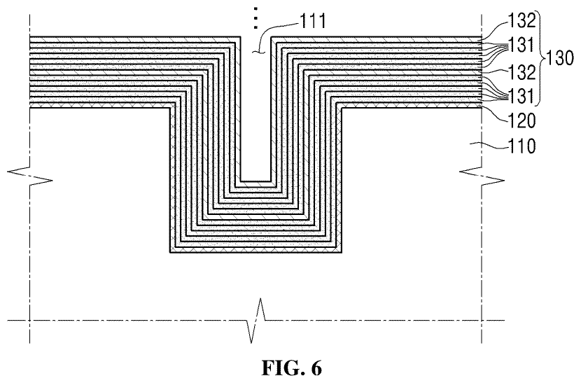

FIG. 6 is a diagram illustrating a capacitor having a lower electrode formed on a substrate in which a trench is formed.

In the above description, the forming of the lower electrode 130 for the capacitor on the flat substrate 110 has been described. However, a shape of the substrate is not limited thereto, and a capacitor may be manufactured by forming the lower electrode 130 on a substrate 110 having a trench 111 as illustrated in FIG. 6 by the method in accordance with the exemplary embodiment illustrated in FIG. 3. That is, the underlayer 120, for example, a contact layer, may be formed on the substrate 110 having the trench 111, and the lower electrode 130 may be formed on the contact layer by the method in accordance with the exemplary embodiment. Of course, in forming the lower electrode on the substrate 110 on which the trench 111 is formed, the lower electrode may be formed by the method in accordance with the modification example of FIG. 5 without being limited to the exemplary embodiment of FIG. 3.

In the above, the case of forming the lower electrode 130 of the capacitor 100 by the methods in accordance with to the exemplary embodiment and the modification example has been described by way of example. However, the methods in accordance with the exemplary embodiment and the modification example may be applied to form the upper electrode 150 and may be applied to both the upper electrode 150 and the lower electrode 130.

As described above, in accordance with the exemplary embodiment, in forming at least one of the upper electrode 150 and the lower electrode 130, the at least one may be formed by stacking the first thin film 131 and the second thin film 132. At this time, when the second thin film 132 is formed, the second thin film 132 is formed using a precursor source containing a noble metal element and not containing chlorine (Cl) and fluorine (F). That is, the second thin film 132 is formed by using a precursor containing at least one of ruthenium (Ru), platinum (Pt), gold (Au), silver (Ag), rhodium (Rh), palladium (Pd), osmium (Os), iridium (Ir), yttrium (Yi), and molybdenum (Mo) and not containing chlorine (Cl) and fluorine (F) as the second source. Accordingly, it is possible to suppress or prevent damage to the underlayer 120 formed beneath the upper electrode 150 or the lower electrode 130 by chlorine (Cl) and fluorine (F).

More specifically, in forming at least one of the upper electrode 150 and the lower electrode 130, the second thin film 132 is provided to contain at least one noble metal element of ruthenium (Ru), platinum (Pt), gold (Au), silver (Ag), rhodium (Rh), palladium (Pd), osmium (Os), iridium (Ir), yttrium (Yi), and molybdenum (Mo), or cupper (Cu). Accordingly, the resistivity of at least one of the upper electrode 150 and the lower electrode 130 may be reduced, and thus electrical characteristics thereof may be improved.

In addition, as the damage to the underlayer 120 is suppressed or prevented and the electrical characteristics of the electrodes is improved, the quality characteristics of the capacitor 100 may be improved.

### INDUSTRIAL APPLICABILITY

In accordance with exemplary embodiments, it is possible to suppress or prevent damage to an underlayer during electrode formation. In addition, it is possible to lower resistivity of an electrode, and there is an effect of improving electrical characteristics of the electrode.

1. A method for forming a capacitor electrode, the method comprising:
preparing a substrate;
forming a first thin film containing titanium (Ti) by injecting a source containing titanium on the substrate; and
forming a second thin film by injecting a source containing a noble metal element or copper (Cu) on the substrate,
wherein the forming of the first thin film is repeated more times than the forming of the second thin film.

2. The method for forming a capacitor electrode of claim 1, wherein the forming of the first thin film and the forming of the second thin film are alternately repeated.

3. The method for forming a capacitor electrode of claim 1, wherein the forming of the second thin film is performed before the forming of the first thin film.

4. The method for forming a capacitor electrode of claim 1, wherein in the forming of the first thin film, TiN atomic layer deposition is continuously performed a plurality of times.

5. The method for forming a capacitor electrode of claim 1, wherein in the forming of the second thin film, a plurality of deposition cycles are continuously performed.

6. (canceled)

7. The method for forming a capacitor electrode of claim 1, wherein a ratio(T₁:T₂) of the number(T₁) of times the forming of the first thin film is executed to the number(T₂) of times the forming of the second thin film is executed is adjusted to 1:1 to 10:1.

8. The method for forming a capacitor electrode of claim 1, wherein the source containing a noble metal element is a precursor containing at least one of ruthenium (Ru), platinum (Pt), gold (Au), silver (Ag), rhodium (Rh), palladium (Pd), osmium (Os), iridium (Ir), yttrium (Yi), and molybdenum (Mo).

9. The method for forming a capacitor electrode of claim 1, wherein the forming of the second thin film comprises:
injecting a reducing gas after injecting the source containing a noble metal element or copper (Cu); and
activating the reducing gas using plasma.

10. The method for forming a capacitor electrode of claim 1, wherein the forming of the second thin film comprises:
injecting a reducing gas after injecting the source containing a noble metal element or copper (Cu); and
exposing the substrate to plasma.
